(19) United States
(12) Patent Application Publication
(10) Pub. No.: US 2019/0244876 A1
(43) Pub. Date: Aug. 8, 2019

(54) Positioning assembly for computer radiator

(71) Applicant: SHU-HUI WANG, Taichung (TW)

(72) Inventor: SHU-HUI WANG, Taichung (TW)

(21) Appl. No.: 15/992,626

(22) Filed: May 30, 2018

(30) Foreign Application Priority Data
Feb. 7, 2018 (TW) 107201863

(51) Int. Cl. H01L 23/40; G06F 1/20; F28F 13/00

(52) U.S. Cl. CPC H01L 23/4006; G06F 1/20; F28F 13/00; H01L 2023/4062; H01L 2023/4081; H01L 2023/4087; H01L 2023/4043; F28F 2275/08

(57) ABSTRACT

A positioning assembly for a computer radiator contains: multiple first shank members, multiple resilient elements, and multiple second shank members. Each of the multiple first shank members includes a first head knob, a first extension, a locking rib, a shoulder, a slot, and an orifice, wherein an outer diameter of the first extension is less than the first head knob, and the locking rib is in a conical cylinder shape. Each of the multiple resilient elements is fitted on the first extension. Each of the multiple shank members includes a second head knob and a second extension extending downward from a bottom of the second head knob, wherein an outer diameter of the second extension is less than an inner diameter of the orifice so that the second extension is located on a lower end of the orifice after inserting into a top of the orifice.

### FIELD OF THE INVENTION

The present invention relates to electronic equipment, and more particularly to a positioning assembly which fixes a computer radiator securely.

### BACKGROUND OF THE INVENTION

A computer is broken easily after a period of using time, because heat produces from chips of the computer. With reference to FIGS. 1-2, a chip 10 is locked with a computer radiator 30 by ways of a plurality of screws 20 so that the chip 10 conducts heats to multiple fins 31, and the heats are dissipated out of the computer by using a fan.

However, it is inconvenient to connect the computer radiator 30 by using the plurality of screws 20.

The present invention has arisen to mitigate and/or obviate the afore-described disadvantages.

### SUMMARY OF THE INVENTION

The primary aspect of the present invention is to provide a positioning assembly which fixes a computer radiator securely.

The present invention may be understood through the following description with reference to the accompanying drawings, in which:

### BRIEF DESCRIPTION OF THE DRAWINGS

FIG. 1 is a perspective view showing the exploded components of a conventional computer radiator.

FIG. 2 is a perspective view showing the assembly of the conventional computer radiator.

FIG. 3 is a perspective view showing a positioning assembly for a computer radiator according to a preferred embodiment of the present invention.

FIG. 4 is a cross sectional view showing the assembly of the positioning assembly for the computer radiator according to the preferred embodiment of the present invention.

FIG. 5 is a perspective view showing the application of the positioning assembly for the computer radiator according to the preferred embodiment of the present invention.

FIGS. 6-9 are a cross sectional view showing the application of the positioning assembly for the computer radiator according to the preferred embodiment of the present invention.

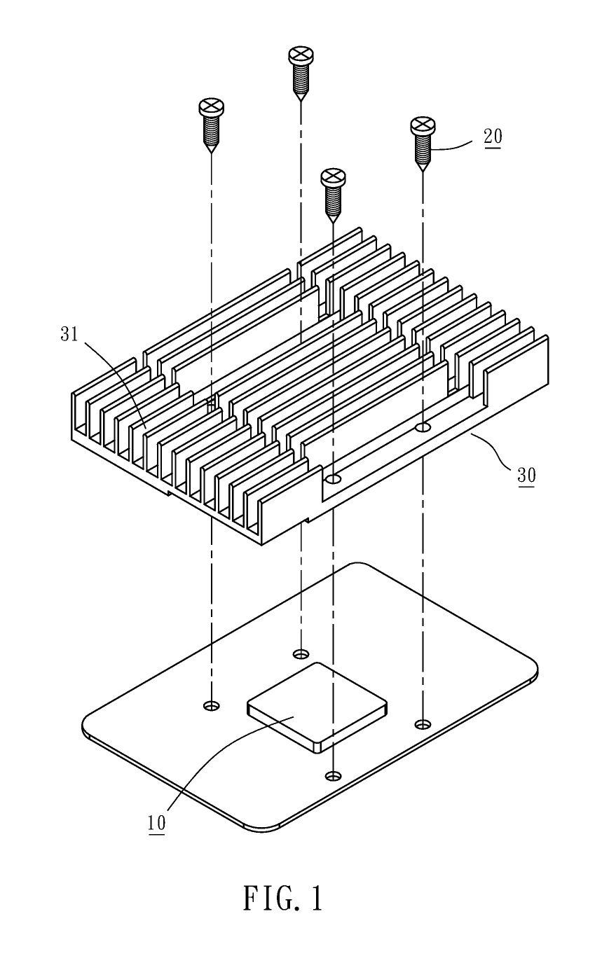

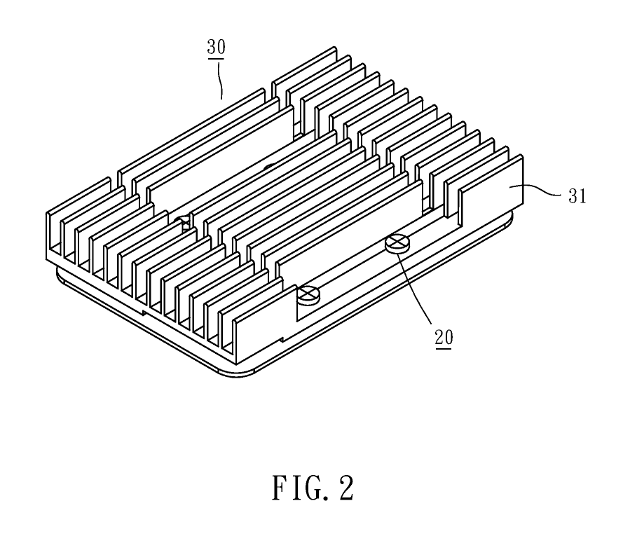

### DETAILED DESCRIPTION OF THE PREFERRED EMBODIMENTS

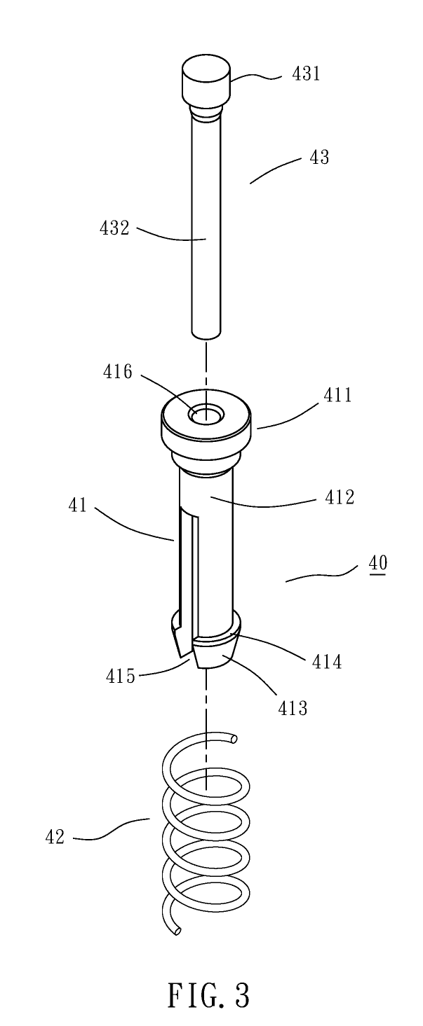

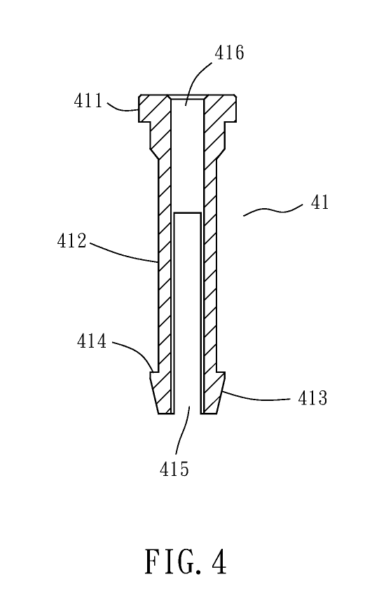

With reference to FIGS. 3 and 4, a positioning assembly 40 for a computer radiator according to a preferred embodiment of the present invention comprises:

multiple first shank members 41, each of the multiple first shank members 41 made of metal material and including a first head knob 411, a first extension 412 extending downward from a bottom of the first head knob 411, a locking rib 413 extending outward from a lower end of the first extension 412, a shoulder 414 defined between the locking rib 413 and the first extension 412, a slot 415 extending to the first extension 412 from a bottom of the locking rib 413, and an orifice 416 extending to a bottom of the slot 415 from a top of the first head knob 411, wherein an outer diameter of the first extension 412 is less than the first head knob 411, and the locking rib 413 is in a conical cylinder shape;

multiple resilient elements 42, each of the multiple resilient elements 42 fitted on the first extension 412;

multiple second shank members 43, each of the multiple shank members 43 made of plastic, and each second shank member 43 including a second head knob 431 and a second extension 432 extending downward from a bottom of the second head knob 431, wherein an outer diameter of the second extension 432 is less than an inner diameter of the orifice 416.

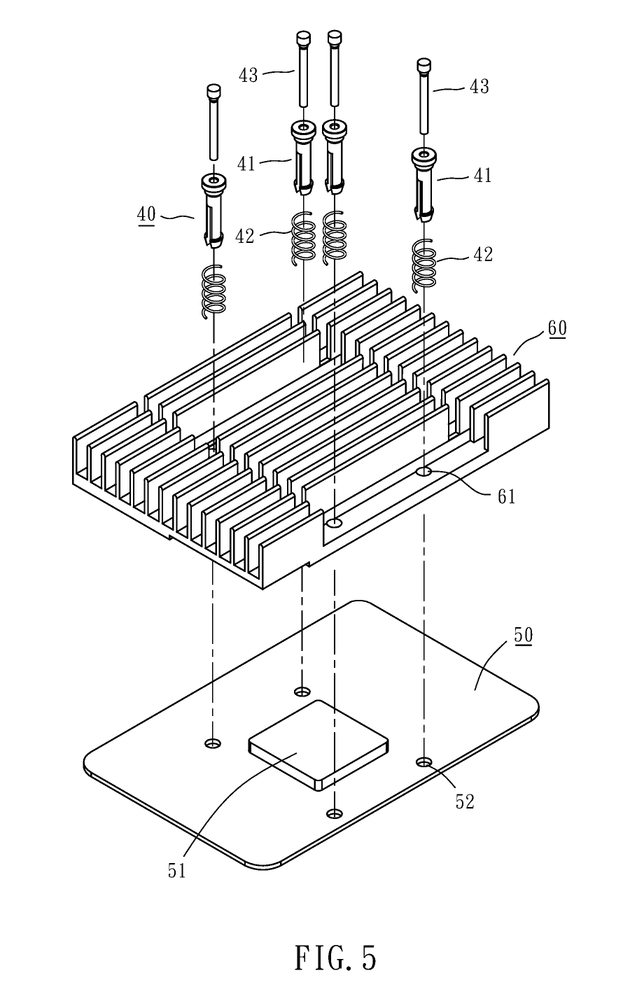

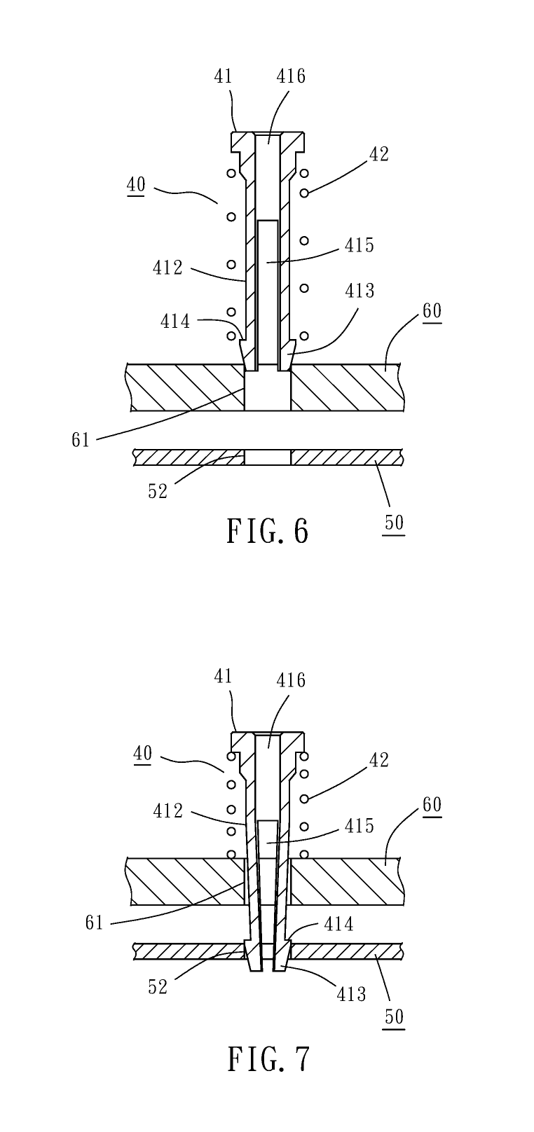

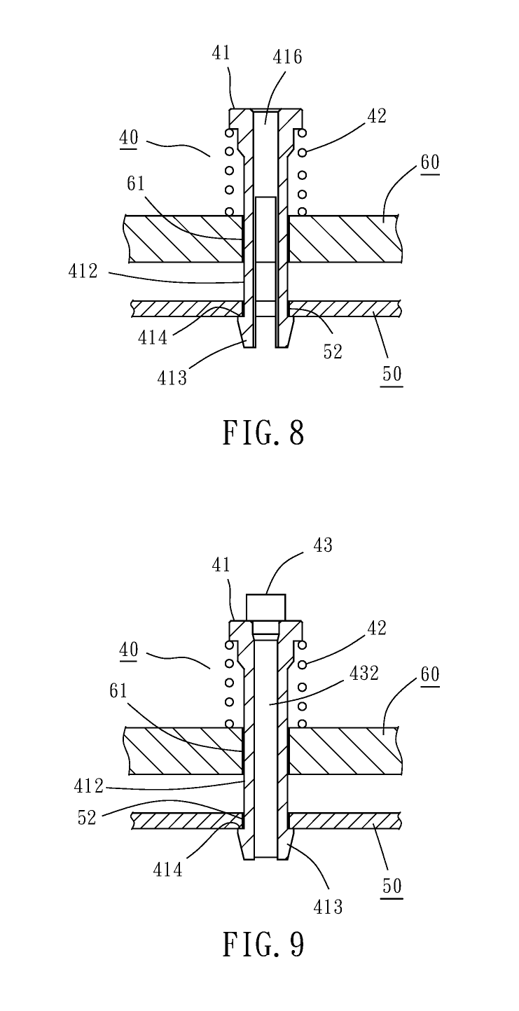

Referring to FIGS. 5-9, a circuit board 50 includes a chip 51 arranged thereon and includes multiple fixing apertures 52 defined on the circuit board 50. The computer radiator 60 includes multiple through holes 61 corresponding to the multiple fixing apertures 52 respectively. As shown in FIG. 6, when the locking rib 413 contacts with each of the multiple through holes 61, the lower end of the first extension 412 shrinks so that the first extension 412 passes through each through hole 61. Then, as illustrated in FIG. 7, the lower end of the first extension 412 passes through each of the multiple fixing apertures 52. With reference to FIG. 8, after the locking rib 413 passes through each fixing aperture 52 completely, the locking rib 413 is not limited, and the first extension 412 recovers its shape and is fixed by the shoulder 414. Referring to FIG. 9, the second extension 432 is located on a lower end of the orifice 416 after inserting into a top of the orifice 416, and the first extension 412 does not shrink so as to avoid a removal of the locking rib 413 from the shoulder 414 and to fix the first shank member 41 securely.

As desiring to detach the computer radiator 60, the second head knob 431 is pressed by user so as to pull each shank member 43 upwardly and to remove the first shank member 41.

In another embodiment, the first shank member 41 is made of copper.

In some embodiments, the shank member 43 is made of nylon or polycarbonates (PC).

In some embodiments, the resilient element 42 is a compression spring.

While the preferred embodiments of the invention have been set forth for the purpose of disclosure, modifications of the disclosed embodiments of the invention and other embodiments thereof may occur to those skilled in the art. Accordingly, the appended claims are intended to cover all embodiments which do not depart from the spirit and scope of the invention.

What is claimed is:

1. A positioning assembly for a computer radiator comprising:
multiple first shank members, each of the multiple first shank members including a first head knob, a first extension extending downward from a bottom of the first head knob, a locking rib extending outward from a lower end of the first extension, a shoulder defined between the locking rib and the first extension, a slot extending to the first extension from a bottom of the locking rib, and an orifice extending to a bottom of the slot from a top of the first head knob, wherein an outer diameter of the first extension is less than the first head knob, and the locking rib is in a conical cylinder shape;
multiple resilient elements, each of the multiple resilient elements fitted on the first extension; and
multiple second shank members, each of the multiple shank members including a second head knob and a second extension extending downward from a bottom of the second head knob, wherein an outer diameter of the second extension is less than an inner diameter of the orifice so that the second extension is located on a lower end of the orifice after inserting into a top of the orifice.

2. A positioning assembly for a computer radiator as in claim 1, wherein said first shank members are made of metal material.

3. A positioning assembly for a computer radiator as in claim 1, wherein said first shank members are made of copper.

4. A positioning assembly for a computer radiator as in claim 2, wherein said first shank members are made of copper.

5. A positioning assembly for a computer radiator as in claim 1, wherein said second shank members are made of plastic.

6. A positioning assembly for a computer radiator as in claim 5, wherein said plastic is selected from the group consisting nylon and polycarbonates (PC).

7. A positioning assembly for a computer radiator as in claim 1, wherein said resilient element is a compression spring.

8. A positioning assembly for a computer radiator as in claim 2, wherein said resilient element is a compression spring.

9. A positioning assembly for a computer radiator as in claim 5, wherein said resilient element is a compression spring.
